(19) United States
(12) Patent Application Publication
(10) Pub. No.: US 2011/0200884 A1
(43) Pub. Date: Aug. 18, 2011

(54) POSITIVE CURRENT COLLECTOR AND MANUFACTURING METHOD THEREOF

(75) Inventor: Yozo Uchida, Aichi (JP)

(73) Assignee: TOYOTA JIDOSHA KABUSHIKI KAISHA, Toyota-shi (JP)

(21) Appl. No.: 13/125,004

(22) PCT Filed: Nov. 13, 2009
(86) PCT No.: PCT/JP2009/069390

§ 371 Date: Apr. 19, 2011

(30) Foreign Application Priority Data
Nov. 13, 2008 (JP) 2008-290826

(51) Int. Cl. H01M 4/66; H01M 4/04; C23C 14/58; C23C 14/34

(52) U.S. Cl. 429/245; 29/623.5; 204/192.35; 204/192.1

(57) ABSTRACT

A positive current collector provided by the present invention is a positive current collector including an electrically conductive layer on a base material of aluminum or an aluminum alloy. The base material has a surface oxide film at an interface of the base material body and the conductive layer, and a thickness of the surface oxide film is 3 nm or less.

### TECHNICAL FIELD

The present invention relates to a positive current collector for use as a battery component, and to a manufacturing method therefor.

The priority claim for this international application is based on Japanese Patent Application No. 2008-290826 submitted on Nov. 13, 2008, and the entire contents of that application are incorporated by reference in this Description.

### BACKGROUND ART

Because they provide high output with low weight, lithium secondary batteries (typically lithium-ion batteries), which are charged and discharged by means of the movement of lithium ions between the positive and negative electrodes, are expected to be in increasing demand as in-car power sources and power sources in personal computers and portable devices. In a typical configuration, this kind of secondary battery has an electrode comprising a material capable of reversibly storing and releasing lithium ions (electrode active material) supported on an electrically conductive member (electrode collector). For example, typical examples of electrode active materials for use in positive electrodes (positive electrode active materials) include oxides comprising lithium and one or two or more transition metal elements as constituent metal elements (hereunder sometimes called “lithium-transition metal oxides”). Typical examples of electrode current collectors for use in positive electrodes (positive current collectors) include sheets or foils consisting mainly of aluminum or aluminum alloys.

Positive current collectors made of aluminum and aluminum alloys are liable to corrosion (such as oxidation). For example, because the surface of a positive current collector made of aluminum or aluminum alloy oxidizes immediately when exposed to air, it has a permanent oxide film. When there is an oxide film on the surface of the current collector, electrical resistance between the positive current collector and the positive electrode active material layer is increased because the oxide film is an insulating film.

Patent Document 1 discloses a technology for controlling such corrosion (alteration) of the collector surface. Patent Document 1 discloses a technique whereby the natural oxide film on the collector surface is first removed with a sputter ion beam etching device, after which a coating layer (carbon film) of carbon or the like having good electrical conductivity and corrosion resistance is provided on the surface of the collector. Other documents of prior art for conferring corrosion resistance on a collector surface include Patent Documents 2, 3 and 4 for example.

Patent Document 1: Japanese Patent Application Laid-open No. H11-250900
Patent Document 2: Japanese Patent Application Laid-open No. H10-106585

### Patent Document 3: Japanese Patent Application Laid-open No. 2005-259682

### Patent Document 4: Japanese Patent Application Laid-open No. 2007-250376

The problem is that because natural oxide films of Al₂O₃ are normally of low etching grade, the process of oxide film removal can be too time-consuming. For example, according to the estimates of the inventors of this application, the etching grade is about 1 nm/min when an oxide film is etched under conditions of sputter power 200 W, capacity 13.5 MHz using a conventional sputtering device. Given a natural oxide film with a thickness of about 5 to 10 nm, it would require 5 to 10 minutes to remove the entire oxide film, resulting in low productivity. A shorter etching time would be useful because the etching process could then be accomplished in a way suited to inline continuous manufacture.

### DISCLOSURE OF THE INVENTION

In light of these facts, the principal object of the present invention is to provide a positive current collector excellent in productivity which is a positive current collector having a conductive layer on the surface thereof, along with a manufacturing method therefor.

The inventors in this case perfected the present invention after discovering that an oxide film of a specific thickness or less actually contributes to improving the stability (durability) of the positive current collector without greatly increasing the resistance between the positive current collector and the positive electrode active material layer.

That is, the positive current collector provided by the present invention is a positive current collector including an electrically conductive layer formed on a base material of aluminum. The base material features a surface oxide film of 3 nm or less in thickness at an interface of the base material body and the conductive layer.

With the positive current collector of the present invention, interposing a surface oxide film (Al₂O₃ layer) that is more chemically stable than simple Al at the interface of the aluminum base material and the conductive layer makes the collector more durable (stable) than a collector without such an oxide film. This helps to extend battery life (or in other words to maintain stable battery performance over a long period of time). In addition, the oxide film (which is an insulating coat) can be made electrically conductive by giving it a thickness of 3 nm or less, so that resistance between the positive current collector and the positive electrode mix layer (layer containing the positive electrode active material) is not dramatically increased. That is, a positive current collector with high output and a long cycle life can be provided by the configuration of the present invention.

In a preferred embodiment of the positive current collector disclosed here, the conductive layer is composed of a metal or metal carbide that is more resistant to corrosion (alteration) than aluminum. Making the conductive layer corrosion resistant is a way of protecting the aluminum base material, which is vulnerable to corrosion.

In a preferred embodiment of the positive current collector disclosed here, the base material is a sheet of aluminum foil. Aluminum is easy to work into a thin film (sheet), which gives it various desirable characteristics as a positive current collector, but also makes it vulnerable to corrosion. Therefore, the effects obtained by adopting the configuration of the present invention in terms of protecting the base material by means of an oxide film and a conductive layer on the base material surface are particularly useful when the base material is an aluminum foil.

The present invention also provides a method for manufacturing a positive current collector. This is a method for manufacturing a positive current collector by laminating an electrically conductive layer on a base material made of aluminum or an aluminum alloy. In this method, a base material having a surface oxide film at the interface of the base material body is prepared as the base material. The method comprises a thickness adjustment step in which the surface oxide film on the prepared base is adjusted by etching to a thickness of 3 nm or less, and a conductive layer formation step in which the conductive layer is formed on the aforementioned surface oxide film with adjusted thickness.

Removing the aluminum oxide film completely is time-consuming because the film is of low etching grade, but because in the method of the present invention a specific thickness of the surface oxide film is left deliberately to function as a stable layer, the time required for etching is greatly reduced, and productivity can be improved.

In a preferred embodiment of the positive current collector manufacturing method disclosed here, the etching is accomplished by sputter etching. In a preferred embodiment of the positive current collector manufacturing method disclosed here, moreover, the conductive layer is formed by sputtering using metal or a metal carbide as a target.

The present invention also provides a secondary battery (lithium-ion battery or other lithium secondary battery for example) constructed using the positive current collector manufactured by any of the methods disclosed here. Because this secondary battery is constructed using the aforementioned positive current collector for the positive electrode, it may exhibit improved battery performance (for example, at least one of low internal resistance, high output characteristics and good durability (stability)).

Such a secondary battery is useful as a secondary battery mounted in an automobile or other vehicle for example. Thus, a vehicle provided with any of the secondary batteries disclosed here (which may be an assembled battery consisting of multiple secondary batteries connected to one another) is provided by the present invention. In particular, because it provides high output with low weight, the battery is preferably a lithium secondary battery (typically a lithium-ion battery), and the vehicle is preferably a vehicle (such as an automobile) provided with this lithium secondary battery as a power source (typically, the power source of a hybrid automobile or electrical automobile).

### BRIEF DESCRIPTION OF THE DRAWINGS

FIG. 1 is a cross-sectional view of the positive electrode of one embodiment of the present invention.

FIG. 2 is a flow chart showing the manufacturing steps for the positive electrode of one embodiment of the present invention.

FIG. 3A is a cross-sectional process drawing illustrating the manufacturing steps for the positive electrode of one embodiment of the present invention.

FIG. 3B is a cross-sectional process drawing illustrating the manufacturing steps for the positive electrode of one embodiment of the present invention.

FIG. 3C is a cross-sectional process drawing illustrating the manufacturing steps for the positive electrode of one embodiment of the present invention.

FIG. 3D is a cross-sectional process drawing illustrating the manufacturing steps for the positive electrode of one embodiment of the present invention.

FIG. 4 shows a device for manufacturing the positive current collector of one embodiment of the present invention.

FIG. 5 is a graph showing the relationship between contact resistance and the thickness of an Al oxide film.

FIG. 6 is a graph showing the relationship between contact resistance and battery capacity at a rate of 100 C.

FIG. 7 is a side view illustrating a vehicle (automobile) equipped with a secondary battery of one embodiment of the present invention.

### BEST MODE FOR CARRYING OUT THE INVENTION

The inventors of the present application conceived of the present invention after discovering that a positive current collector with superior durability and productivity could be obtained by deliberately leaving part of the natural film occurring on the surface of a positive current collector (aluminum foil), rather than removing the entire film.

Embodiments of the present invention are explained below with reference to the drawings. In the drawings below, parts and areas having the same effects are explained using the same symbols. The dimensional relationships (length, width, thickness and the like) in the drawings do not reflect the actual dimensional relationships. Matters not specifically mentioned in this Description which are necessary for implementing the present invention, (for example, methods for manufacturing the positive electrode active material, methods for preparing the composition for forming the electrode mix layer, the configurations and preparation methods of the separators and electrolytes, and general techniques for constructing lithium secondary batteries and other batteries and the like) can be understood as design matters by a person skilled in the art based on prior art in the technical field.

Although this is not intended as a limitation, the positive current collector of these embodiments is mainly explained below using the example of positive collector 10 for a lithium secondary battery (typically a lithium-ion battery) having a foil base material made of aluminum (aluminum foil), and positive electrode 30 equipped with this positive current collector.

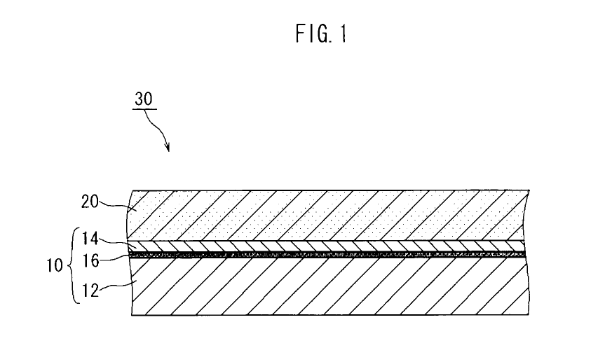

As shown in FIG. 1, positive electrode 30 for a lithium secondary battery disclosed here comprises positive current collector 10 and positive electrode mix layer (layer containing positive electrode active material) 20, which is supported on positive current collector 10.

Positive current collector 10 is formed by laminating conductive layer 14 on base material 12. Base material 12 is made of aluminum or an aluminum alloy, since these have excellent conductivity and are easily worked into thin films (sheets). In this embodiment, base material 12 (that is, the base material body) is an aluminum foil about 10 μm to 30 μm thick.

Conductive layer 14 consisting of an electrically conductive material is formed so as to cover base material 12. Conductive layer 14 is interposed between base material 12 and positive electrode mix layer 20, and acts to lower the interface resistance between base material 12 and positive electrode mix layer 20. Conductive layer 14 is preferably of a material with low electrical resistance, with a resistivity of preferably 500 μΩ·cm or less, or more preferably 50 μΩ·cm or less. In this embodiment, conductive layer 14 is made of tungsten carbide (resistivity 17 μΩ·cm). The thickness of conductive layer 14 is generally in the range of 5 nm to 100 nm, or about 20 nm in this embodiment.

In addition, surface oxide film 16 is formed on the surface of base material 12 (that is, at the interface of the base material and conductive layer 14). Surface oxide film 16 consists of an aluminum oxide such as Al₂O₃, and is produced for example by natural oxidation of surface of the base material (natural oxide film). Because such an Al₂O₃ coat (oxide film) 16 is more chemically stable than simple Al, it serves to improve the durability (stability) of the current collector over that of a current collector without an oxide film.

The thickness of surface oxide film 16 can be about 3 nm or less. The tunnel effect of surface oxide film 16 is much greater if it has a thickness of 3 nm or less. This means that the Al oxide film (which is normally an insulating coat) can be made electrically conductive, so that electrical resistance between the positive current collector and the positive electrode mix layer (layer containing positive electrode active material) is not greatly increased.

The lower limit of the thickness of surface oxide film 16 can be such that the underlying aluminum (base material) is covered without being exposed. For example, it can be the thickness of one molecule of Al₂O₃ (monomolecular layer). For example, the thickness of surface oxide film 16 is at least 0.5 nm but no more than 3 nm, or preferably at least 1 nm but no more than 3 nm. In this way, the underlying aluminum (base material body) can be uniformly covered by surface oxide film 16, thereby helping to improve the stability (durability) of the positive current collector.

With positive current collector 10 of this embodiment, because surface oxide film (Al₂O₃ layer) 16, which is more chemically stable than simple Al, is interposed between the aluminum base material 12 and conductive layer 14, the durability (stability) of the collector is greater than that of a collector having no oxide film 16. It is thus possible to extend the life of the battery (or in other words to maintain stable battery performance over a long period of time). Because the thickness of surface oxide film 16 is 3 nm or less, moreover, the oxide film (which is an insulating coat) can also be made electrically conductive, so that resistance between positive current collector 10 and the positive electrode mix layer (layer containing the positive electrode active material) is not dramatically increased. That is, a positive current collector 10 with high output and a long cycle life is provided by the configuration of this embodiment.

Conductive layer 14 above is preferably composed of a metal or metal carbide that is both electrically conductive and more resistant to corrosion than aluminum. Making conductive layer 14 corrosion resistant in this way helps to protect aluminum base material 12, which is vulnerable to corrosion. Examples of such metal materials include stainless (SUS) and other kinds of steel, hafnium (Hf), tantalum (Ta), zirconium (Zr), vanadium (V), chromium (Cr), molybdenum (Mo), niobium (Nb), tungsten (W) and the like, or alloys of these (such as nickel-chromium (Ni—Cr) alloy). Examples of carbon materials include carbon (C) as well as WC, TaC, HfC, NbC, Mo₂C, VC, Cr₃C₂, TiC, ZrC and other metal carbides. Of these, tungsten (W) or tungsten carbide (WC) is particularly desirable. A material can be evaluated for corrosion resistance as necessary by a corrosion test matching the anticipated corrosion environment.

Positive electrode mix layer 20 can be any layer containing a positive electrode active material for a lithium secondary battery. In this embodiment, positive electrode mix layer 20 is composed of a positive electrode active material together with other positive electrode mix layer-forming components (such as a conduction aid, a binder and the like) as necessary. It is desirable to use a positive electrode active material that is composed primarily of a lithium-transition metal composite oxide containing lithium and one or two or more transition metal elements as constituent metal elements for example. Desirable examples include LiMn₂O₄, LiCoO₂, LiNiO₂, LiFePO₄, LiMnPO₄, LiNiMnCoO₂ and the like.

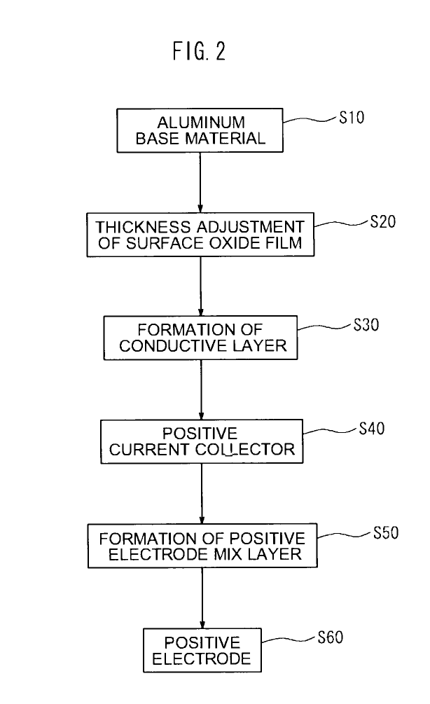

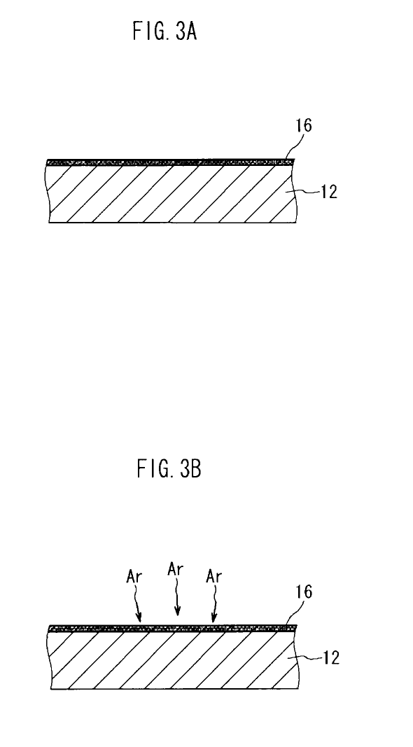

Next, a method for manufacturing positive electrode 30 having positive current collector 10 is explained with reference to FIG. 2 and FIGS. 3A through 3D. In this embodiment, the natural oxide film occurring on base material 12 is used as stable layer (surface oxide film) 16 at the interface of base material 12 and conductive layer 14.

That is, as shown in FIG. 2, a base material (aluminum foil) having an oxide film formed on the surface thereof is prepared (S10), and the surface oxide film on base material 12 is adjusted by etching to a thickness of 3 nm or less (S20). Conductive layer 14 is then formed on thickness-adjusted surface oxide film 16 (S30) to prepare positive current collector 10 (S40). Positive electrode mix layer 20 is then coated on conductive layer 14 of positive current collector 10 (S50) to obtain positive electrode 30 of this embodiment (S60).

Aluminum oxide films (natural oxide films) are time-consuming to remove completely because they are of low etching grade, but in the method of the present invention the time required for etching is greatly reduced because natural oxide film 16 is used as a stable layer, and is allowed to remain intentionally. For example, the inventors of the present application have estimated that when an oxide film is etched with a standard sputtering device under conditions of sputtering power 200 W and capacity 13.5 MHz, the etching rate is about 1 nm/min. If the thickness of the natural oxide film produced on an aluminum foil (collector) is about 5 nm, it will require 5 minutes to completely remove the natural oxide film. By contrast, since at least 2 nm needs to be removed in this embodiment, the processing time can be as short as 2 minutes. That is, productivity of the collector is greatly improved with the method of the present invention because the etching time can be reduced by 50% or more.

FIGS. 3A through 3D are further explained in detail. FIGS. 3A through 3D are cross-sectional process drawings illustrating the manufacturing process for the positive current collector.

First, aluminum or aluminum alloy base material 12 is prepared as shown in FIG. 3A. In this embodiment it is aluminum foil. Because aluminum foil oxidizes immediately when exposed to air, the base material body has surface oxide film (natural oxide film) 16 on its surface. The thickness of surface oxide film 16 varies according to environmental conditions and the like and is therefore not particularly limited, but is normally about 5 nm or more.

Next, a shown in FIG. 3B, surface oxide film 16 of base material 12 is etched to adjust the thickness to 3 nm or less (preferably at least 1 nm but no more than 3 nm) (thickness adjustment step). The etching can be accomplished by dry etching for example. The type of dry etching is not particularly limited, and for example ion bombardment by discharge plasma can be used. In this embodiment, part of oxide film 16 is removed by sputter etching using Ar gas. Because the etching rate of aluminum oxide film by Ar sputtering is relatively low, it takes a long time to completely remove the oxide film, but because in this embodiment a specific thickness or less of aluminum oxide film 16 (preferably at least 1 nm but no more than 3 nm) is left behind, the etching time can be shorter than in the case of complete removal. The etching method is not limited to sputtering, and another etching method can be used. The etching time will also be shorter in this case.

Once the thickness of surface oxide film 16 has been adjusted to 3 nm or less, conductive layer 14 is formed on natural oxide film 16 (which is now 3 nm or less), as shown in FIG. 3C. The method of forming conductive layer 14 is not particularly limited, and for example a physical vapor deposition (PVD) deposition method such as sputtering, ion plating (IP), arc ion plating (AIP) or the like or a chemical vapor deposition (CVD) method such as plasma CVD can be used. In this embodiment, the conductive layer is formed by sputtering using an electrically conductive material (such as WC) for the target. Further oxidation on the surface of the base material (formation of a new natural oxide film) can be controlled by forming conductive layer 14 on surface oxide film 16.

It is thus possible to prepare positive current collector 10 having conductive layer 14 laminated on base material 12, wherein positive current collector 10 has surface oxide film 16 with a thickness of 3 nm or less at the interface of base material 12 and conductive layer 14.

Once positive current collector 10 has been prepared, positive electrode mix layer 20 is formed on conductive layer 14 as shown in FIG. 3D. Positive electrode mix layer 20 can be formed for example by coating and drying a positive electrode mix paste on top of conductive layer 14. The positive electrode mix paste can be prepared by dispersing a powder of the positive electrode active material together with other positive electrode mix layer-forming components (such as a conduction aid, a binder and the like) as necessary in a suitable dispersion solvent, and kneading the mix. The dispersion solvent may be water or a mixed solvent consisting primarily of water, or may be a non-aqueous organic medium (such as N-methyl pyrrolidone).

When using water or a mixed solvent consisting primarily or water, the lithium ions of the lithium-transition metal composite oxide may produce alkalinity when they are eluted in the aqueous medium, but with the manufacturing method of this embodiment conductive layer 14 functions as a protective coat, and can prevent reactions (typically, corrosion caused by alkali) between the aqueous composition and base material 12.

It is thus possible to obtain positive electrode 30 provided with positive current collector 10 of this embodiment. The thickness and density of positive electrode mix layer 20 can also be adjusted as necessary by suitable pressing treatment (such as roll pressing) after drying.

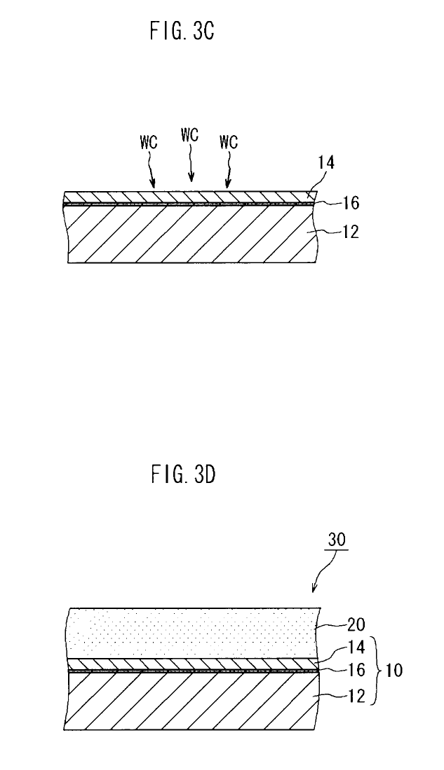

FIG. 4 shows one example of manufacturing device 90 for manufacturing positive current collector 10 of this embodiment. Manufacturing device 90 is equipped with chamber 91, the interior of which can be depressurized, gas inlet 92 for introducing gas into chamber 91, and base material holder 93 for holding base material 12 in chamber 91. Etching part 95 and conductive layer-forming part 96 are also provided inside chamber 91.

Gas inlet 92 introduces gas into chamber 91, forming a gas atmosphere in chamber 91. The introduced gas is inactive gas for example (Ar gas in this embodiment). Active gas can also be added as necessary.

Etching part 95 etches surface oxide film 16, which is produced on the surface of base material 12. Etching part 95 can be any device capable of dry etching, and is a sputtering device in this case. Etching part 95 etches surface oxide film on base material 12, adjusting the thickness of the film to 3 nm or less. The amount of oxide film that is etched can be controlled for example by suitably adjusting the sputtering conditions and the transport speed of the base material.

Conductive layer-forming part 96 forms conductive layer 14 on surface oxide film 16, which has been adjusted to a thickness of 3 nm or less. In this embodiment, conductive layer-forming part 96 is a sputtering device, which sputters using a target of a conductive material (WC in this case) to thereby form a film of the conductive material on surface oxide film 16, which has been adjusted to a thickness of 3 nm or less.

Base material holder 93 holds base material 12 inside chamber 91, and also transports base material 12 either continuously or intermittently. In this embodiment, base material 12 is a sheet of aluminum foil having surface oxide film 16. This aluminum foil 12 is pulled from roll 97 and transported inside chamber 91 by the rotation of base material holder 93. It is then subjected to thickness adjustment treatment by etching part 95 to adjust the thickness of surface oxide film 16 to 3 nm or less, and to film-formation treatment with a conductive material by conductive layer-forming part 96, and then spooled onto roll 98 as positive current collector 10. The spooled positive current collector 10 is then sent to the step of forming positive electrode mix layer 20.

With manufacturing device 90 of this embodiment, a positive current collector 10 having oxide film 16 with a thickness of 3 nm or less at the interface of base material 12 and conductive layer 14 can be obtained with good productivity because it is possible to continuously etch (adjust the thickness of) surface oxide film 16 and form conductive layer 14 as the sheet of base material 12 is transported either continuously or intermittently. Productivity is further improved because surface oxide film 16 is not completely removed by etching of surface oxide film 16.

Because the positive current collector of this embodiment has excellent current-collection performance as discussed above, it can be used favorably as a component of various kinds of batteries, or as a component (such as a positive electrode) of an electrode body contained in such a battery. For example, it can be used favorably as a component of a lithium secondary battery equipped with a positive electrode having any of the positive current collectors disclosed here, a negative electrode, an electrolyte disposed between the positive and negative electrodes, and typically a separator (which may be omitted if the battery uses a solid or gel electrolyte) separating the positive and negative electrodes. There are no particular limitations on the size and structure (metal case or laminate film structure for example) of the outer container of the battery, or on the structure (coiled structure or layered structure for example) of the electrode body having positive and negative current collectors as principal components.

A battery constructed in this way exhibits superior battery performance because the base material surface is strongly protected by aluminum oxide film 16 and conductive layer 14, and because the battery is provided with the positive current collector 10 having excellent current-collecting performance with respect to the positive electrode mix layer 20. For example, a battery with excellent output characteristics can be provided by constructing a battery using this positive current collector.

Next, the relationship between the Al oxide film thickness and the contact resistance of the positive current collector was investigated.

Changes in the contact resistance of the positive current collector were investigated as the thickness of the Al₂O₃ film between the base material and conductive layer was altered. Specifically, an aluminum foil was first prepared as the base material, and the natural oxide film formed on the surface of this aluminum foil was completely removed by sputter etching. An Al₂O₃ film of a specific thickness was then formed on the aluminum foil surface from which the oxide film had been completely removed. The Al₂O₃ film was formed with an ordinary sputtering device. The Al₂O₃ film was formed using an Al₂O₃ target, with Ar gas and O₂ gas introduced into the sputtering device (Ar flow rate 17 sccm, O₂ flow rate 0.34 sccm). The sputter power was set to 200 W, the sputter pressure to 6.7×10⁻¹ Pa, and the attained pressure to 3.0×10⁻³ Pa.

Next, a WC layer (thickness 100 nm) was formed as a conductive layer on the resulting Al₂O₃ film, to prepare a positive current collector. The WC layer was formed using an ordinary sputtering device. The WC layer was formed using a tungsten carbide (WC) target, with Ar gas introduced into the sputtering device (Ar flow rate 11.5 sccm). The sputter power was set to 200 W, the sputter pressure to 6.7×10⁻¹ Pa, the attained pressure to 3.0×10⁻³ Pa, and the film-forming time to 30 min.

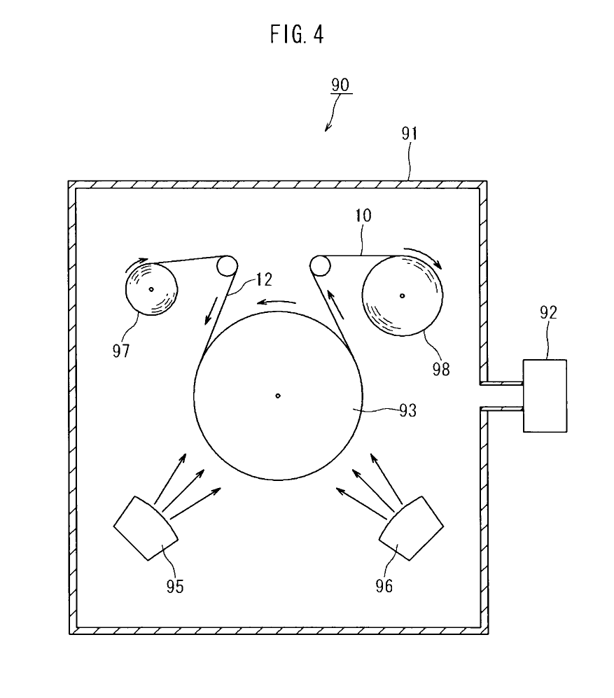

Positive current collectors each having a different Al₂O₃ film thickness were prepared by altering the thickness of the Al₂O₃ film between the base material and the WC layer. Specifically, positive current collectors were prepared with Al₂O₃ film thicknesses of 0 nm (no Al₂O₃ film), 1 nm, 3 nm, 5 nm and 10 nm. Fixed current was then supplied to each of the resulting positive current collectors, and contact resistance was calculated from the resulting changes in voltage characteristics. The results are shown in FIG. 5. The horizontal axis in FIG. 5 shows the thickness of the Al₂O₃ film (nm), while the vertical axis shows the contact resistance (mΩ·cm²).

As shown in FIG. 5, when the thickness of the Al₂O₃ film between the base material and WC layer was 5 nm and 10 nm, the resistance value exceeded 1.5 mΩ·cm², but when the thickness of the Al₂O₃ film was 3 nm or less, the resistance value was 0.5 mΩ·cm² or less—a dramatic decrease in resistance. This confirms that if the Al oxide film on the base material surface is adjusted to 3 nm or less, an Al film can be interposed between the positive current collector and the positive active material layer without increasing the resistance between the positive current collector and positive active material layer, resulting in a good improvement in battery characteristics.

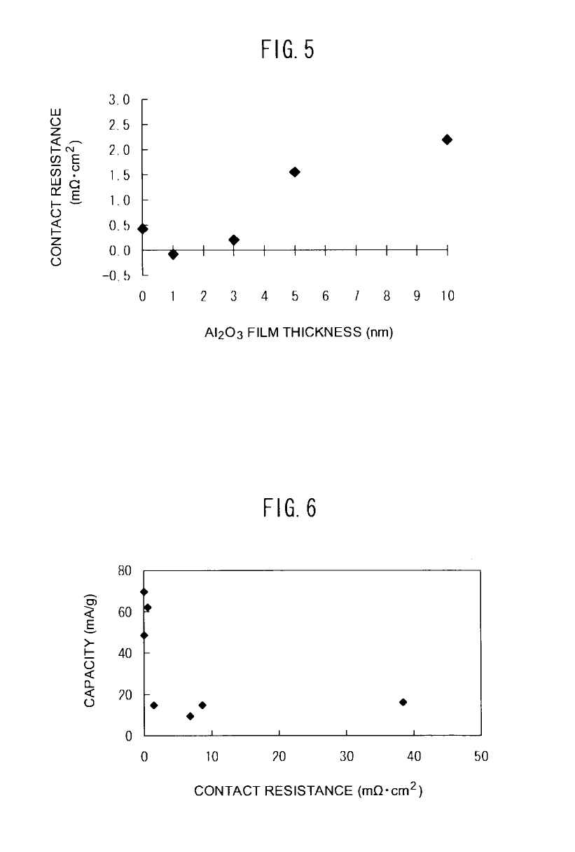

The relationship between battery characteristics and contact resistance of the positive current collector is shown as a reference example in FIG. 6. FIG. 6 shows test results from an investigation of changes in the battery capacity (100 C capacity) of coin cells at a discharge rate of 100 C when the contact resistance of the positive current collector was altered by altering the materials of the conductive layer and base material as shown in Table 1 below, using test coin cells constructed using positive current collectors with conductive layers on the base material surface. The horizontal axis in FIG. 6 shows contact resistance (mΩ·cm²) of the positive current collector, and the vertical axis shows the 100 C capacity (mΩ·cm²) of the coin cell.

As shown in FIG. 6, the 100 C capacity of the coin cell is dramatically increased when the contact resistance of the positive current collector is 1 mΩ·cm² or less. This means that the battery characteristics (especially the high-rate battery characteristics) can be improved by adjusting the film thickness of the surface oxide film on the base material to 3 nm or less, thereby keeping the resistance of the positive current collector at 1 mΩ·cm² or less.

The aforementioned test coin cells were constructed as follows. In the case of Test Example 4 in Table 1 for example, aluminum foil was used as the base material, and the natural oxide film on the aluminum foil surface was completely removed by sputter etching. After removal of the oxide film, a WC layer was formed as a conductive layer (thickness 20 nm) on the surface of the aluminum foil, to prepare a positive current collector for use in a test coin cell. When measured, the contact resistance of the resulting positive current collector was 0.06 mΩ·cm². Positive current collectors with different contact resistance values were also prepared by altering the materials of the base material and conductive layer as shown by Test Examples 1 to 7 in Table 1 below. In Test Example 1, an untreated Al film having the natural oxide film remaining on the surface of the aluminum foil was used as the positive current collector. In Test Example 2, a base material of pure gold was used as the positive current collector.

TABLE 1

| | | Contact | Battery capacity of coil cell at each discharge rate | | | | | | | | |
|---|---|---|---|---|---|---|---|---|---|---|---|
| | Foil | resistance | ⅓ C | 1 C | 5 C | 10 C | 20 C | 30 C | 50 C | 80 C | 100 C |
| Test Ex. 1 | Untreated Al foil | 8.44 | 126.2 | 120.8 | 111.2 | 105.6 | 98.8 | 92.7 | 66.2 | 18.3 | 15.1 |
| TE 2 | Pure gold foil | 0.05 | 102.3 | 97.1 | 88.1 | 83.3 | 76.0 | 71.5 | 64.6 | 55.1 | 48.6 |
| TE 3 | C sputtered Al foil (AIP method) | 1.33 | 125.0 | 119.5 | 110.6 | 105.8 | 99.0 | 94.5 | 73.0 | 18.5 | 15.1 |
| TE 4 | WC sputtered Al foil | 0.06 | 118.0 | 113.3 | 104.5 | 100.0 | 93.8 | 89.2 | 82.6 | 75.9 | 69.8 |
| TE 5 | SUS316 sputtered Al foil | 0.46 | 104.9 | 100.6 | 92.5 | 87.9 | 82.5 | 78.8 | 72.9 | 66.7 | 62.1 |
| TE 6 | Hf sputtered Al foil | 6.7 | 113.5 | 109.6 | 99.8 | 93.3 | 76.2 | 57.3 | 31.2 | 20.1 | 9.7 |
| TE 7 | TiC sputtered Al foil | 38.25 | 115.6 | 110.7 | 104.9 | 96.6 | 89.5 | 84.8 | 72.2 | 20.1 | 15.9 |

Coin cells for testing were constructed using the positive current collectors of Test Examples 1 to 7 obtained above, and the battery capacity of the coin cells was measured at each discharge rate. As shown in Table 1, the battery capacity at a high rate of discharge (especially 50 C or more) increases as the contact resistance of the positive current collector decreases. It appears from these results that the high-rate characteristics of a coin cell depend greatly on the contact resistance of the positive current collector. Apart from the positive current collector, the various other constituent battery materials (such as the positive active material, negative electrode, electrolyte between positive and negative electrodes, separator separating positive and negative electrodes and the like) were prepared in the same way as known constituent battery materials in the field of lithium secondary battery manufacture.

The present invention has been explained by means of preferred embodiments, but these do not limit the invention, and various modifications are of course possible. For example, the battery need not be a lithium-ion secondary battery as described above, and batteries of various kinds with different electrode materials and electrolytes are possible, such as nickel hydrogen batteries, nickel cadmium batteries, lithium ion capacitors, metal air batteries and the like.

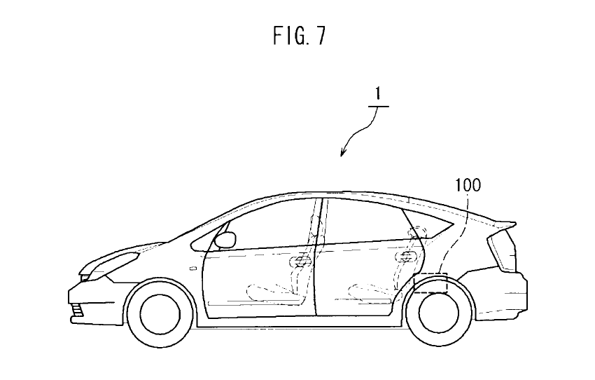

Because the battery of this embodiment has excellent durability and high-rate capacity as described above, it can be used favorably as a motor power source mounted in an automobile or other vehicle. That is, as shown in FIG. 7, vehicle 1 (typically an automobile, especially a hybrid automobile, electrical automobile, fuel cell automobile or other automobile equipped with a motor) can be provided having as a power source assembled battery 100, which is constructed by arraying secondary batteries of this embodiment as single batteries in a specific direction, and confining these single batteries in the array direction to construct an assembled battery.

### INDUSTRIAL APPLICABILITY

With the configuration of the present invention, a positive current collector having a surface conductive layer can be provided which is a positive current collector with excellent productivity, along with a manufacturing method therefor.

1. A positive current collector comprising an electrically conductive layer laminated on a base material of aluminum or an aluminum alloy, wherein
the base material has a surface oxide film at an interface of the base material body and the conductive layer, and a thickness of the surface oxide film is adjusted to 3 nm or less by etching.

2. The positive current collector according to claim 1, wherein the conductive layer is composed of a metal or metal carbide that is more resistant to corrosion caused by alkali than aluminum.

3. The positive current collector according to claim 2, wherein the conductive layer is composed of tungsten or tungsten carbide.

4. The positive current collector according to claim 1, wherein the base material is a sheet of aluminum foil.

5. A method for manufacturing a positive current collector equipped with an electrically conductive layer laminated on a base material of aluminum or aluminum alloy, the method comprising:
a step of preparing as the base material a base material having a surface oxide film on a surface of the base material body;
a thickness adjustment step of adjusting a thickness of the surface oxide film on the base material to a thickness of 3 nm or less by etching; and
a conductive layer formation step of forming the conductive layer on the surface oxide film with the adjusted thickness.

6. The manufacturing method according to claim 5, wherein the etching is performed by sputter etching.

7. The manufacturing method according to claim 5, wherein the conductive layer is formed by sputtering using metal or a metal carbide as a target.

8. The manufacturing method according to claim 5, wherein the base material is a sheet of aluminum foil.

9. A method for manufacturing a lithium secondary battery, wherein the positive current collector manufactured by the manufacturing method according to claim 5 is used as the positive current collector.

10. A secondary battery equipped with the positive current collector according to claim 1.

11. A secondary battery equipped with the positive current collector according to claim 2.

12. A secondary battery equipped with the positive current collector according to claim 3.

13. The secondary battery according to claim 10, constructed as a lithium secondary battery.

14. A vehicle equipped with the secondary battery according to claim 10.
